(19) United States
(12) Patent Application Publication
(10) Pub. No.: US 2013/0316593 A1
(43) Pub. Date: Nov. 28, 2013

(54) Joint Connector and Method for Testing for Partial Terminal Insertion

(71) Applicant: Yazaki Corporation, Tokyo (JP)

(72) Inventor: Tomohiko Shimizu, Makinohara-shi (JP)

(73) Assignee: YAZAKI CORPORATION, Tokyo (JP)

(21) Appl. No.: 13/955,670

(22) Filed: Jul. 31, 2013

Related U.S. Application Data
(63) Continuation of application No. PCT/JP2012/053170, filed on Feb. 10, 2012.

(30) Foreign Application Priority Data
Feb. 18, 2011 (JP) 2011-033712

(51) Int. Cl. H01R 13/422; G01R 27/02

(52) U.S. Cl. CPC H01R 13/4223; G01R 27/02
USPC 439/660; 324/691

(57) ABSTRACT

A joint terminal 10 can be retained, at one housing end part 31 where the joint terminal 10 is to be accommodated, between a completely latched position where tab pieces 11 come into a regular fitted state or become conductively connectable to female terminal fittings 20 inserted in respective terminal accommodation chambers 34, and a tentatively latched position that is shallower than the completely latched position and where the tab pieces 11 are conductively connectable solely to the female terminal fittings 20 inserted up to a specified position in each of the terminal accommodation chambers 34.

### CROSS REFERENCE TO RELATED APPLICATION

This application is a continuation of PCT application No. PCT/JP2012/053170, which was filed on Feb. 10, 2012 based on Japanese Patent Application No. 2010-033712 filed on Feb. 18, 2011, the contents of which are incorporated herein by reference. Also, all the references cited herein are incorporated as a whole.

### BACKGROUND OF THE INVENTION

1. Field of the Invention

The present invention relates to a joint connector capable of detecting a partially-inserted terminal state and to a method for testing for partial terminal insertion using the joint connector.

2. Description of the Related Art

For instance, a joint connector described in connection with JP-A-2000-243502, or the like, has hitherto been known as; for instance, a related art joint connector that is used in branch connection of an automobile wire harness. As shown in FIG. 8, a joint connector 100 has a female connector housing (connector housing) 120 that accommodates a plurality of pieces of female terminal fittings (female terminal fittings) 140 and a joint housing 130 outfitted with joint terminals 132 to be joined to the respective pieces of female terminal fittings 140.

A state of a fit between the female connector housing 120 and the joint housing 130 includes fitted states; namely, a tentatively fitted state in which the joint housing 130 is shallowly fitted into the female connector housing 120 and a completely fitted state in which the joint housing 130 is further deeply fitted into the female connector housing 120, whereby the pieces of female terminal fittings 140 and tabs (tab pieces) 134 of the respective joint terminals 132 are connected together.

If the pieces of female terminal fittings 140 are in a partial insertion state and have not yet reached normal positions on occasions when the housings 120 and 130 shift from the tentatively fitted state to the completely fitted state, lances 122 stay resiliently deformed in respective deflection spaces 123. Accordingly, leading ends of deflection regulation sections 136 provided in the joint housing 130 contact the corresponding lances 122 and cannot be inserted any further. Thus, the joint connector is configured such that the partially-inserted state of the female terminal fittings 140 is thereby detected.

Moreover, as shown in FIG. 9, a joint connector 200 described in connection with JP-A-2004-207157 is made up of female terminal fittings (female terminal fittings) 210, a connector housing 220 into which the female terminal fittings 210 is to be accommodated, a bus bar 230 for short-circuiting the pieces of female terminal fittings 210, and a retaining member 240 for retaining the bus bar 230.

In the connector housing 220, the retaining member 240 is arranged so as to be able to switch between a completely latched position where tab pieces 233 of the bus bar 230 remain in proper contact with a connection section (an electrical connection section) 212 of the female terminal fittings 210 and a tentatively latched position where the tab pieces 203 stay out of contact with the connection section 212.

The connector housing is configured such that, when the tab pieces 233 have contacted the connection section 212 of the female terminal fittings 210 in a partially-inserted state during the course of the retaining member 240 being displaced from the tentatively latched position to the completely latched position, a worker can ascertain from a sense of contact that the female terminal fittings 210 is in the partially-inserted state.

Any of the related art joint connectors, however, is configured such that the joint terminal is previously retained by the joint housing or the retaining member, which is made from a synthetic resin, and that removal and insertion of the joint terminal are performed by attaching and removing the joint housing and the retaining member to and from the connector housing.

Accordingly, the joint housing or the retaining member, which is made from a synthetic resin, is required, which raises a problem of an increase in the number of components.

A state in which the female terminal fittings is partially-inserted into the related art joint connector is detected by visual inspection or by a sense of contact that the worker feels in the course of displacing the joint housing and the retaining member to the completely fitted state and the completely latched position.

Accordingly, when there is an increase in number of tabs, there is also an augmentation of actuation forces required when the joint housing and the retaining member are displaced to the completely fitted state and the completely latched position, whilst the sense of contact becomes weaker. Thus, it becomes difficult for the worker to perform sensory ascertainment. For these reasons, the related art joint connector has a drawback in a potential risk of erroneous detection of a partially-inserted state of the terminal.

### SUMMARY OF THE INVENTION

The present invention has been conceived in light of the circumstance and aims at providing a joint connector that requires a smaller number of components and that can detect a partially-inserted terminal without fail and a partially-inserted terminal inspection method.

To accomplish the objective, a joint connector and a method for testing for partial terminal insertion using the joint connector of the present invention have characteristics (1) to (4) provided below.

(1) A joint connector comprising:

a plurality of pieces of female terminal fittings;

a joint terminal having a plurality of tab pieces to be fit-connected to the respective pieces of female terminal fittings and a joining section for conductively connecting the tab pieces; and

a connector housing that is made from a synthetic resin and that has one housing end part which accommodates and holds the joint terminal while the tab pieces are oriented toward another housing end part and the other housing end part with a plurality of terminal accommodation chambers which bring the female terminal fittings and the corresponding tab pieces into a fitted state when the female terminal fittings is inserted up to a specified position, wherein the joint terminal can be retained, at the one housing end part, between a completely latched position where the tab pieces come into a regular fitted state, or become conductively connectable to the female terminal fittings inserted in the respective terminal accommodation chambers, and a tentatively latched position that is shallower than the completely latched position and where the tab pieces are conductively connectable solely to the female terminal fittings inserted up to the specified position in each of the terminal accommodation chambers.

(2) In the joint connector with the configuration (1), the joint terminal is equipped with completely latching projections that are projectingly provided in the joining section and latched by the one housing end part and tentatively latching projections that are projectingly provided in an area of the joining section closer to the tab pieces when compared with the completely latching projections and that are latched at the one housing end part.

(3) In the joint connector with the configuration (2), the one housing end part has tentatively latch recesses that retain the joint terminal at the tentatively latched position by latching the tentatively latching projections.

(4) A method for testing for partial terminal insertion using the joint connector having the configuration (1), comprising:

retaining the joint terminal at the tentatively latched position with respect to the one housing end part, subsequently inspecting electrical conductivity between the joint terminal and the pieces of female terminal fittings while the pieces of female terminal fittings remain inserted up to the specified position in each of the terminal accommodation chambers, and detecting absence of electrical conductivity between the joint terminal and the pieces of female terminal fittings as a partially-inserted terminal state.

In the joint connector having the configuration (1), since the joint terminal is retained directly at the one housing end part of the connector housing, the number of components can be reduced.

In addition, during assembly of the joint connector, the joint terminal can be retained at the tentatively latched position on the one housing end part that is shallower than the completely latched position. Subsequently, the pieces of female terminal fittings are inserted up to the specified position in each of the terminal accommodation chambers while the joint terminal is retained at the tentatively latched position. Then, the joint terminal can be displaced to the completely latched position, thereby bringing the tab pieces and the pieces of female terminal fittings into a regular fitted state. Accordingly, when inserted into the respective terminal accommodation chambers, the pieces of female terminal fittings do not come into the regular fitted state in which all inserting forces exerted on the tab pieces act on the pieces of female terminal fittings, so that a terminal inserting force can be kept small.

In addition, during assembly of the joint connector, after the joint terminal is retained at the tentatively latched position at the one housing end part, electrical conductivity between the joint terminal and the pieces of female terminal fittings can be inspected while the pieces of female terminal fittings are inserted up to the specified position in each of the terminal accommodation chambers. Accordingly, when electrical conductivity does not exist between the joint terminal and the pieces of female terminal fittings, a partially-inserted state of the pieces of female terminal fittings can be detected, and hence the pieces of female terminal fittings can be prevented from becoming partially-inserted.

In the joint connector having the configuration (2), the joint terminal can be retained without fail at the completely latched position or the tentatively latched position at the one housing end part by means of the completely latching projections or the tentatively latching projections that are easy to form and assume a simple shape. In particular, the joint terminal can be doubly latched at the completely latched position by means of the completely latching projections and the tentatively latching projections.

In the joint connector having the configuration (3), the joint terminal can be accurately retained at the tentatively latched position by causing the tentatively latch recesses to latch the tentatively latching projections.

According to the method for testing for partial terminal insertion including the configuration (4), after the joint terminal of the joint connector having any the configuration (1) is retained at the tentatively latched position, absence of electrical conductivity between the pieces of female terminal fittings inserted into the respective terminal accommodation chambers and the joint terminal is detected, whereby the female terminal fittings can be determined to be in a partially-inserted terminal state by detection. Accordingly, the female terminal fittings can be reliably prevented from entering a partially-inserted terminal state by means of a simple structure that has a smaller number of components.

The present invention can provide a joint connector and a method for testing for partial terminal insertion that require a smaller number of components and that enable reliable detection of a partially-inserted terminal state.

The present invention has been briefly described thus far. Details of the present invention will be more clarified by reading through a mode (hereinafter called an “embodiment”) for implementing the present invention to be described below by reference to the accompanying drawings.

### BRIEF DESCRIPTION OF THE DRAWINGS

FIG. 1 is an exploded perspective view of a joint connector of an embodiment of the present invention.

FIG. 2 is a bottom view of a connector housing shown in FIG. 1.

FIG. 3 is a horizontal cross sectional view for explaining a partially-inserted terminal inspection process effected during insertion of female terminal fittings into the connector housing shown in FIG. 1.

FIG. 4 is a longitudinal cross sectional view for explaining the partially-inserted terminal inspection process effected during insertion of the female terminal fittings into the connector housing shown in FIG. 1.

FIG. 5 is a longitudinal cross sectional view for explaining the partially-inserted terminal inspection process effected during insertion of the female terminal fittings into the connector housing shown in FIG. 1.

FIG. 6 is a longitudinal cross sectional view for explaining the partially-inserted terminal inspection process effected during insertion of the female terminal fittings into the connector housing shown in FIG. 1.

FIG. 7 is a horizontal cross sectional view for explaining the partially-inserted terminal inspection process effected during insertion of the female terminal fittings into the connector housing shown in FIG. 1.

FIG. 8 is a longitudinal cross sectional view of a related art joint connector.

FIG. 9 is a longitudinal cross sectional view of another related art joint connector.

### DESCRIPTION OF THE PREFERRED EMBODIMENTS

A joint connector of an embodiment of the present invention is hereunder described in detail by reference to the accompanying drawings.

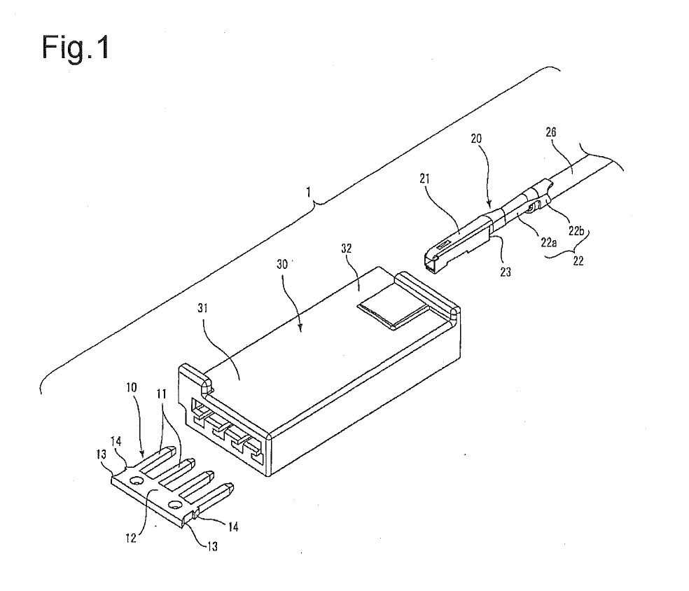

As shown in FIG. 1, a joint connector 1 of the embodiment has a joint terminal 10, female terminal fittings 20, and a connector housing 30.

The joint terminal 10 is an article that is formed from a metal plate by pressing. A plurality of (four in the embodiment) tab pieces 11 to be fit-connected to respective pieces of female terminal fittings 20 and a joining section 12 that conductively interconnects the tab pieces 11 are integrally formed on the joint terminal 10. Moreover, a pair of wedge-shaped completely latching projections 13 and a pair of wedge-shaped tentatively latching projections 14 that are projectingly formed forward of the respective completely latching projections 13 are provided integrally on both lateral edges of the joining section 12.

Each of the pieces of the female terminal fittings 20 is an article formed from a metal plate by pressing and includes, as shown in FIG. 1, a rectangular-tube-like box (an electrical connection section) 21 and into which the corresponding tab piece 11 is to be fitted, an electric cable caulking section 22 that extends from a rear end of the individual box section 21 and that crimps a corresponding electric cable 26, and a retaining-latching section 23.

The electric cable caulking section 22 includes a conductor caulking piece 22a which crimps a conductor of the electric cable 26 to thereby form electrical conductivity and a sheath caulking piece 22b that fixes the electric cable 26 when swaged to the sheath of the electric cable 26.

The retaining-latching section 23 is a recess formed at a rear end of the box section 21 and latches on a corresponding latching lance 36 of the connector housing 30 to be described later, thereby retaining the pieces of female terminal fittings 20.

The connector housing 30 is an article formed from a resin by injection molding and includes one housing end part 31 and another housing end part 32 that is on the other side of the one housing end part 31.

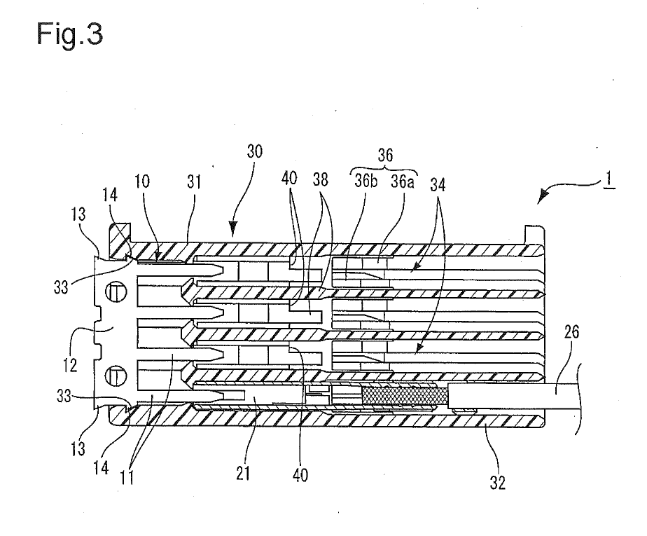

As shown in FIG. 3 and FIG. 7, the one housing end part 31 accommodates and retains, in a tentatively latched position (a position shown in FIG. 3) or a completely latched position (a position shown in FIG. 7), the joint terminal 10 that is press-fitted into the housing while the tab pieces 11 are oriented toward the other housing end part 32.

In the connector housing 30 of the embodiment, tentatively latch recesses 33 are formed in respective interior sidewalls of the one housing end part 31. Accordingly, the joint terminal 10 press-fitted to the tentatively latched position is accurately retained at the tentatively latched position by letting the pair of tentatively latch projections 14, which are provided projectingly on both lateral edges of the joining section 12, latch on the tentatively latch recesses 33. As a matter of course, the tentatively latch recesses 33 can also be omitted by accurately controlling a press-fitting stroke.

As shown in FIG. 3, a plurality of terminal accommodation chambers 34 are placed side by side at the other housing end part 32. As a result of the pieces of the female terminal fittings 20 being inserted up to the specified position, the plurality of terminal accommodation chambers 34 bring the box section 21 and the tab pieces 11 into a fitted state. The expression “specified position” means a location where there is acquired a contact length which is necessary and sufficient for establishing an electrical connection between the tab pieces 11 retained in the completely latched position and the box section 21.

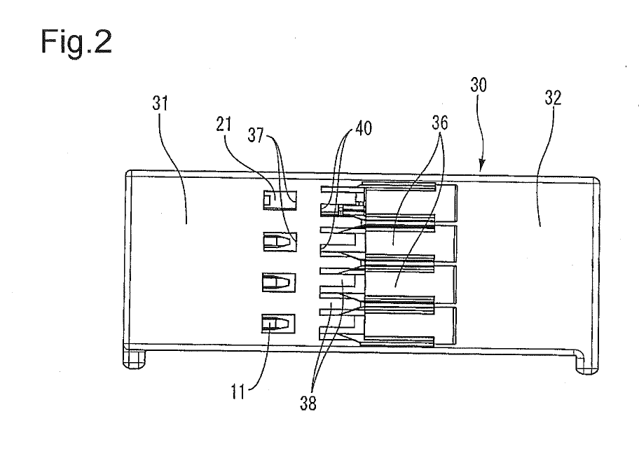

As shown in FIG. 2 and FIG. 3, a latching lance 36, a tab visual-observation window 37, and probe insert opening 40 are provided in a one-to-one relationship and in a bottom wall of the individual terminal accommodation chambers 34.

As shown in FIG. 3 to FIG. 5, the individual latching lance 36 is equipped with an elastic arm 36a that is extended toward the one housing end part 31 along the terminal accommodation chamber 34 and a terminal latching projection 36b that is projectingly provided on an interior surface of a free end of the elastic arm 36a.

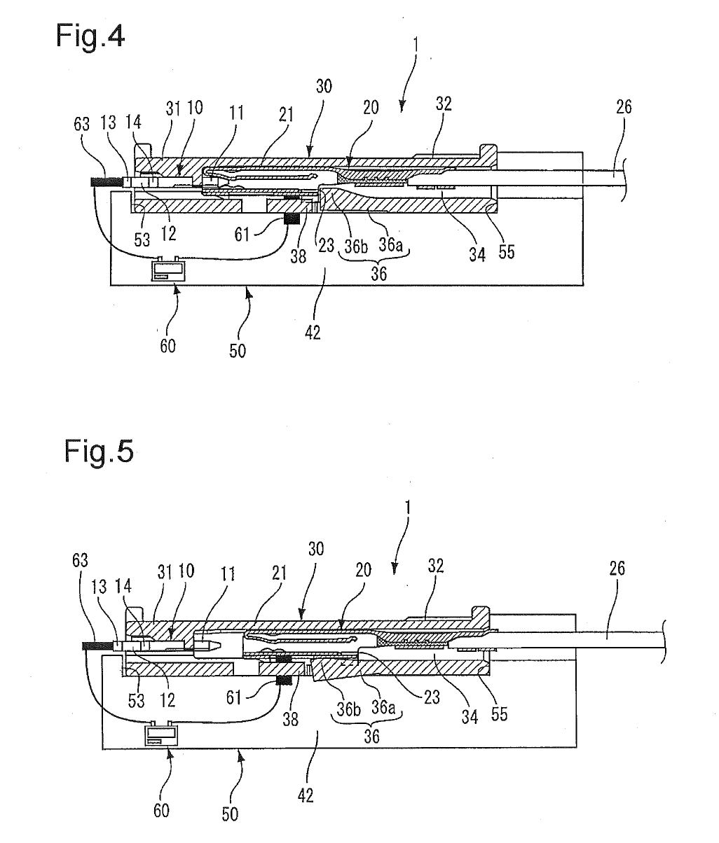

The terminal latching projection 36b protrudes toward an interior of the corresponding terminal accommodation chamber 34 and comes into engagement with the retaining-latching section 23 of the piece of female terminal fittings 20 inserted up to the specified position as shown in FIG. 4, thereby retaining the female terminal fittings 20.

As shown in FIG. 2, each of the tab visual-observation windows 37 is opened at a location where the leading end of the corresponding tab piece 11 can be visually observed and enables visual observation of a state in which the box section 21 is fitted to the tab piece 11.

As shown in FIG. 2 and FIG. 3, the probe insert opening 40 is opened in an area of the individual latching lance 36 that faces the one housing end part 31. A one-polarity-side probe 61 of a conductivity tester 60 to be described later is inserted into the corresponding terminal accommodation chamber 34 from below by way of the probe insert opening 40.

The probe insert opening 40 of the embodiment is made up of a plurality of comb-shaped projections 38 that are formed in a part of a bottom wall of the terminal accommodation chamber 34 so as to extend toward another housing end part 32. Accordingly, the probe insert opening 40 can be easily formed in the connector housing 30 by means of integral molding.

The joint connector 1 of the embodiment obviates a necessity for use of a joint holder, or the like, because the joint terminal 10 is retained directly at the one housing end part 31 of the connector housing 30. Hence, the joint connector of the embodiment can be reduced in the number of components when compared with the related art joint connector.

By reference to FIG. 3 to FIG. 7, an explanation is now given to a partially-inserted terminal inspection process that is implemented when the female terminal fittings 20 is inserted into the connector housing 30 by use of a partially-inserted terminal inspection device 50.

As shown in FIG. 3 to FIG. 5, the partially-inserted terminal inspection device 50 has a base 42 on which a bottom wall of the connector housing 30 with the probe insert openings 40 is to be rested, end support surfaces 53 and 55 that contact end faces of the one housing end part 31 and the other housing end part 32 of the connector housing 30 rested on the base 42, thereby regulating movement of the connector housing 30 in a direction of insertion and removal of the terminals (in a horizontal direction in FIG. 3), and the conductivity tester 60.

The conductivity tester 60 has the one-polarity-side probes 61 that come into contact with the respective pieces of female terminal fittings 20 when inserted into the respective probe insert openings 40; another-polarity-side probes 63 that come into contact with a rear end of the joint terminal 10 fitted into the connector housing 30; and lead wires connected respectively to the probes 61 and 63. The one-polarity-side probes 61 embedded in the base 42 are supported by means of an unillustrated vertically actuating mechanism so as to be able to enter or exit from interiors of the respective terminal accommodation chambers 34 by way of the respective probe insert openings 40.

Accordingly, the conductivity tester 60 can detect electrical conductivity between the joint terminal 10 and the female terminal fittings 20.

On the occasion when partially-inserted terminal inspection is performed during insertion of the female terminal fittings 20 into the connector housing 30, the joint terminal 10 is first press-fitted, as shown in FIG. 2, up to a tentatively latched position of the one housing end part 31 while the connector housing 30 is rested on the base 42 of the partially-inserted terminal inspection device 50.

As shown in FIG. 3, the tentatively latched position of the joint terminal 10 press-fitted into the one housing end part 31 is a location where only the pieces of female terminal fittings 20 inserted up to the specified position in each of the terminal accommodation chambers 34 become conductively connectable, and corresponds to a press-fitted position that is shallower than the completely latched position. Namely, the piece of female terminal fittings 20 that is not inserted up to the specified position in each of the terminal accommodation chambers 34 is not conductively connected to the joint terminal 10.

In this regard, the connector housing 30 in which the joint terminal 10 is previously inserted up to a tentatively latched position at the one housing end part 31 can also be rested on the base 42 of the partially-inserted terminal inspection device 50.

As mentioned above, during assembly of the joint connector 1 of the embodiment, the female terminal fittings 20 is inserted up to the specified position in each of the terminal accommodation chambers 34 while the joint terminal 10 is retained at the tentatively latched position at the one housing end part 31 that is shallower than the completely latched position. Subsequently, the joint terminal 10 is displaced to the completely latched position, thereby bringing the tab pieces 11 and the female terminal fittings 20 into a regular fitted state.

Accordingly, when inserted into the terminal accommodation chambers 34, the pieces of female terminal fittings 20 do not come into a regular fitted state in which all inserting forces exerted on the tab pieces 11 act on the pieces of female terminal fittings 20. Therefore, a terminal inserting force can be kept small.

As shown in FIG. 3, the one-polarity-side probes 61 of the conductivity tester 60 are inserted from the probe insert openings 40 into the interiors of the respective terminal accommodation chambers 34 in the connector housing 30 that is rested on the base 42 of the partially-inserted terminal inspection device 50, being brought into contact with the respective pieces of female terminal fittings 20 inserted in the respective terminal accommodation chambers 34. In addition, the other-polarity-side probes 63 are brought into contact with the rear end of the joint terminal 10.

The conductivity tester 60 detects a state of electrical conductivity between the joint terminal 10 and the respective pieces of female terminal fittings 20 inserted in the respective terminal accommodation chambers 34.

As shown in FIG. 3, if the respective pieces of female terminal fittings 20 are inserted at this time up to the specified position in each of the terminal accommodation chambers 34 and if there is achieved a state in which a contact length that is necessary and sufficient for an electrical connection between the box section 21 and the tab pieces 11 is obtained, the conductivity tester 60 detects a state of electrical conductivity. Accordingly, a completely-inserted terminal state of the female terminal fittings 20 can be detected.

In contrast, as shown in FIG. 4, if the female terminal fittings 20 is not inserted up to the specified position in each of the terminal accommodation chambers 34 and if an electric connection does not exist between the box section 21 and the tab pieces 11, the conductivity tester 60 detects absence of electrical conductivity. Accordingly, a partially-inserted state of the female terminal fittings 20 can be detected.

The female terminal fittings 20 determined to be in the partially-inserted terminal state by inspection is repeatedly subjected to inserting operation until all of the pieces of female terminal fittings 20 are inserted up to the specified position and until the conductivity tester 60 detects a state of electrical conductivity.

Next, by use of a terminal pressing jig 70, the rear end of the joint terminal 10 is pressed, as shown in FIG. 5, against the joint connector 1 whose female terminal fittings 20 is determined to be in a completely-inserted terminal state by inspection, thereby press-fitting the joint terminal 10 up to the completely latched position at the one housing end part 31. In this respect, since the joint terminal 10 press-fitted up to the completely latched position is doubly latched by the completely latching projections 13 and the tentatively latching projections 14, the joint terminal is retained by the one housing end part 31 without fail.

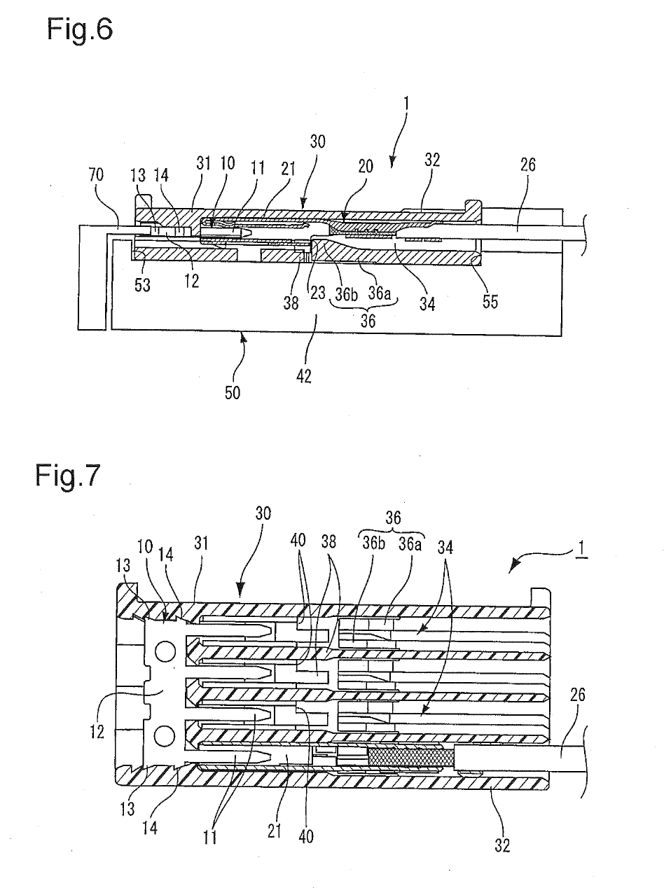

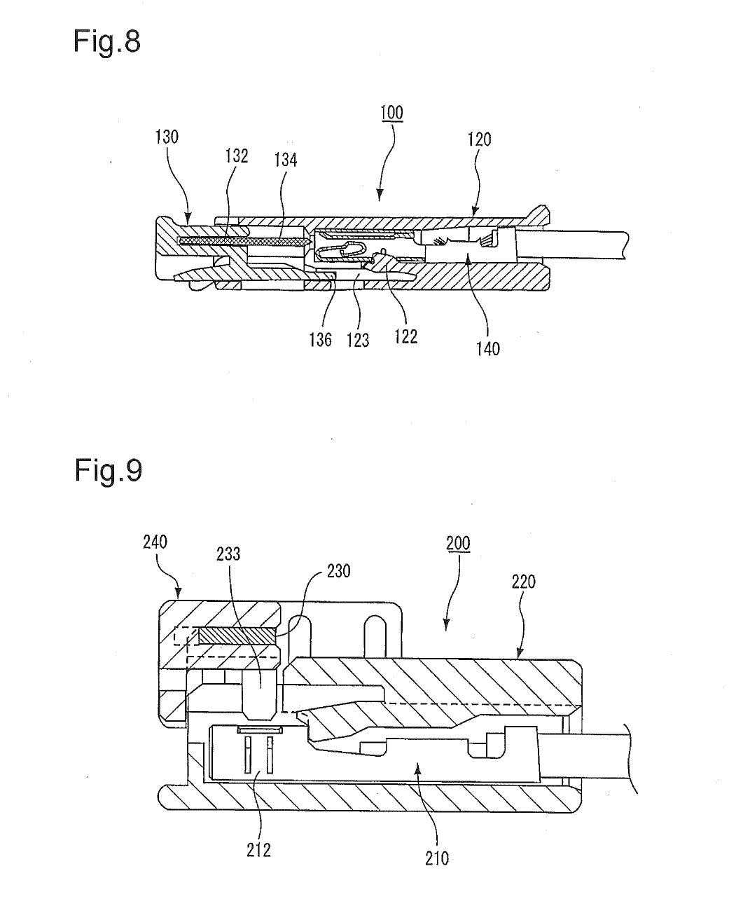

When the joint terminal 10 is press-fitted up to the completely latched position at the one housing end part 31, the box section 21 and the tab pieces 11 are brought into a regular fitted state as shown in FIG. 6, whereupon assembly of the joint connector 1 is completed.

Consequently, during assembly of the joint connector 1 of the embodiment, the joint terminal 10 can be retained at the tentatively latched position at the one housing end part 31 that is shallower than the completely latched position. The female terminal fittings 20 is inserted up to the specified position in each of the terminal accommodation chambers 34 while the joint terminal 10 is retained at the temporarily latched position. Subsequently, the tab pieces 11 and the female terminal fittings 20 can be brought into a regular fitted state by displacing the joint terminal 10 to the completely latched position. Accordingly, when inserted into the terminal accommodation chambers 34, the pieces of female terminal fittings 20 do not come into the regular fitted state in which all the inserting forces exerted on the tab pieces 11 act on the female terminal fittings 20; hence, the terminal inserting force can be kept small.

Further, after the joint terminal 10 is retained at the tentatively latched position at the one housing end part 31 on occasion of assembly of the joint connector 1, electrical conductivity between the joint terminal 10 and the female terminal fittings 20 can be inspected while the pieces of female terminal fittings 20 are inserted up to the specified position in each of the terminal accommodation chambers 34. Accordingly, when electrical conductivity does not exist between the joint terminal 10 and the female terminal fittings 20, the female terminal fittings 20 can be determined to be in a partially-inserted terminal state by inspection, so that the female terminal fittings 20 can be prevented from becoming partially-inserted.

The female terminal fittings, the joint terminal, the completely latching projections, the tentatively latch projections, the connector housing, the tentatively latch recesses, the box, and the probe insert openings, and the like, of the joint connector of the present invention are not limited to those described in connection with the embodiment in terms of a configuration. Needless to say, a variety of configurations can be adopted in light of the gist of the present invention.

Although the present invention has been described in detail by reference to the specific embodiment, it is obvious to those who are versed in the art that the present invention be susceptible to various alterations and modifications without departing the spirit and scope of the present invention.

The present invention can provide a joint connector that involves use of a smaller number of components and a partially-inserted terminal inspection method that allows detection of a partially-inserted terminal state without fail.

1. A joint connector comprising:
a plurality of pieces of female terminal fittings;
a joint terminal having a plurality of tab pieces to be fit-connected to respective pieces of the female terminal fittings and a joining section for conductively connecting the tab pieces; and
a connector housing that is made from a synthetic resin and that has one housing end part which accommodates and holds the joint terminal so that the tab pieces are oriented toward another housing end part and the other housing end part with a plurality of terminal accommodation chambers which bring the female terminal fittings and the corresponding tab pieces into a fitted state when the female terminal fittings is inserted up to a specified position;
wherein the joint terminal can be retained, at the one housing end part, between a completely latched position where the tab pieces come into a regular fitted state, or become conductively connectable to the female terminal fittings inserted in the respective terminal accommodation chambers, and a tentatively latched position that is shallower than the completely latched position and where the tab pieces are conductively connectable solely to the female terminal fittings inserted up to the specified position in each of the terminal accommodation chambers.

2. The joint connector according to claim 1, wherein the joint terminal is equipped with completely latching projections that are projectingly provided in the joining section and latched by the one housing end part and tentatively latching projections that are projectingly provided in an area of the joining section closer to the tab pieces when compared with the completely latching projections and that are latched at the one housing end part.

3. The joint connector according to claim 2, wherein the one housing end part has tentatively latch recesses that retain the joint terminal at the tentatively latched position by latching the tentatively latching projections.

4. A method for testing for partial terminal insertion using a joint connector having any one of claims 1 to 3, the method comprising:
retaining the joint terminal at the tentatively latched position with respect to the one housing end part;
subsequently inspecting electrical conductivity between the joint terminal and the pieces of female terminal fittings while the pieces of female terminal fittings remain inserted up to the specified position in each of the terminal accommodation chambers; and
detecting absence of electrical conductivity between the joint terminal and the pieces of female terminal fittings as a partially-inserted terminal state.
